(19) United States
(12) Patent Application Publication
(10) Pub. No.: US 2023/0120951 A1
(43) Pub. Date: Apr. 20, 2023

(54) Voltage Current Conversion Device

(71) Applicant: Nippon Telegraph and Telephone Corporation, Tokyo (JP)

(72) Inventors: Masayuki Hashisaka, Musashino-shi, Tokyo (JP); Koji Muraki, Musashino-shi, Tokyo (JP); Takafumi Akiho, Musashino-shi, Tokyo (JP)

(21) Appl. No.: 17/911,019

(22) PCT Filed: Mar. 18, 2020
(86) PCT No.: PCT/JP2020/012150

§ 371 Date: Sep. 12, 2022

(51) Int. Cl. H02M 1/088

(52) U.S. Cl. CPC H02M 1/088

(57) ABSTRACT

FETs used in a conventional current-to-voltage converter lack current-to-voltage conversion efficiency when operated at cryogenic temperatures, and it is difficult to sensitively measure current. A desired low-temperature environment cannot be realized either due to the heat inflow into a cooling device from outside. A current-to-voltage converter is provided that sensitively measures small currents even in extremely low-temperature conditions. The current-to-voltage converter of the present disclosure uses elements exclusively optimized for low-temperature operation (e.g., HEMTs) as electronic elements for current-to-voltage conversion. Significantly more excellent current-to-voltage conversion characteristics than those of the conventional technique are realized even when the current-to-voltage converter is operated at a low temperature of 150K or less or in cryogenic temperature conditions close to absolute zero. Power supply to the current-to-voltage conversion circuit and a bias circuit are simplified, and the heat inflow into the cooling device from outside is suppressed, thus reducing the load on the cooling device.

### TECHNICAL FIELD

The present invention relates to an electronic circuit that converts current to voltage.

### BACKGROUND ART

It is known that in order to measure the current, a target current is converted to a voltage and is measured using a voltmeter. To accurately read a small current, it is necessary to convert the current to a voltage using a low-noise electronic circuit. In order to realize this, a method of reducing thermal noise by using a current-to-voltage converter at a low temperature is used. For current signals in the ultra-long to short wave band (1 kHz to 30 MHz), a current-to-voltage converter using low-power field-effect transistors (FETs) that operate at low temperatures has been reported (NPL 1).

FIG. 1 shows a schematic configuration of a current-to-voltage conversion circuit of a conventional current-to-voltage converter (NPL 1). In a current-to-voltage conversion circuit 10, a terminal (current source) from which a target current to be measured flows is connected to an input terminal 11, and a converted voltage corresponding to the target current is measured at an output terminal 14. Current-to-voltage conversion is realized by amplifying signals using four FETs (H1 to H4) and feeding back a source output signal of H4 at the final stage to a gate of H1 on the input side. The conventional current-to-voltage conversion circuit uses generally available FETs that operate at room temperature. For example, the current-to-voltage converter of NPL 1 uses pseudomorphic high electron mobility transistors (HEMT: High Electron Mobility Transistors).

### CITATION LIST

### Non Patent Literature

Hashisaka et. al., “Cross-correlation measurement of quantum shot noise using homemade transimpedance amplifiers”, 2014, Rev. Sci. Instrum. 85, 054704

PAM-XIAMEN GaAs HEMT Epi wafer product catalog page, [online], retrieved on Mar. 6, 2020, Internet <URL: https://www.powerwaywafer.com/gaas-hemt-epi-wafer.html

### SUMMARY OF THE INVENTION

### Technical Problem

However, the open-loop gain of a signal amplification unit is not sufficient in the conventional current-to-voltage converter using FETs capable of operating at room temperature. Very small signals are measured in a current-to-voltage converter when, for example, measuring cosmic rays, quantum device signals, or “quantum fluctuations” of a current, or observing physical phenomena at low temperatures. In order to measure such small currents, it is necessary to operate the current-to-voltage converter at a very low temperature, at least at the temperature of liquid nitrogen (77K) to closer to absolute zero. The FETs used in the conventional technology current-to-voltage converter are based on the premise of operating at room and low temperatures. For this reason, even if these FETs are operated at cryogenic temperatures, the current-to-voltage conversion efficiency is insufficient, and sensitive current measurement is difficult. Further, a desired low-temperature environment cannot be realized with a cooling system due to power consumption of the current-to-voltage converter or heat inflow from outside when used in a cooled state.

The present invention has been made in view of the foregoing problems, and an object of the invention is to provide a means for sensitively measuring small currents in extremely low-temperature conditions.

### Means for Solving the Problem

To achieve the above object, one embodiment of the present invention is a current-to-voltage converter including: an amplification unit having at least three stages each including an electronic element and configured to convert a target current, which is fed to a first stage, to a voltage while feeding back an output signal of a final stage to the first stage; and a buffer unit connected to the amplification unit and configured to output the converted voltage, wherein the electronic element is a field-effect transistor (FET) adapted to operation at a temperature of 150 K or less, a gate of the FET is connected to a ground potential, and a single common power supply is fed to each FET.

### Effects of the Invention

A means for sensitively measuring small currents in extremely low-temperature conditions is provided.

### BRIEF DESCRIPTION OF DRAWINGS

FIG. 1 shows a schematic configuration of a conventional current-to-voltage conversion circuit.

FIG. 2 illustrates a configuration for low-temperature operation of a current-to-voltage converter.

FIG. 3 shows a configuration of a current-to-voltage conversion circuit of a current-to-voltage converter of the present disclosure.

### DESCRIPTION OF EMBODIMENTS

The following disclosure relates to a current-to-voltage converter that sensitively measures small currents even in extremely low-temperature conditions. A current-to-voltage converter of the present disclosure uses elements optimized specifically for low-temperature operation (e.g., HEMTs) as electronic elements for current-to-voltage conversion. This configuration makes it possible to achieve significantly more excellent current-to-voltage conversion characteristic than those of the conventional technique even if the current-to-voltage converter is operated at a low temperature of 150 K or less or in cryogenic temperature conditions close to absolute zero. Further, the configuration of power supply to the current-to-voltage conversion circuit is simplified, and the heat inflow from outside the cooling device is suppressed, thus reducing the load on the cooling device.

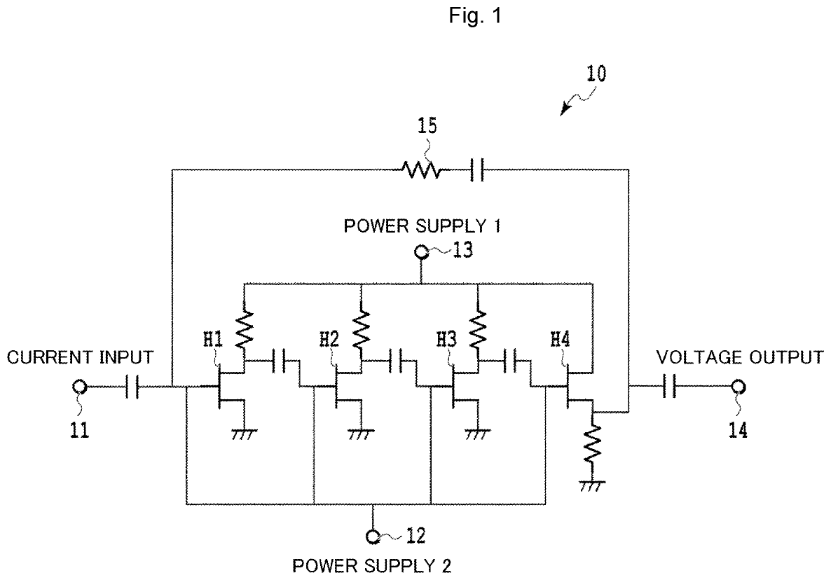

Referring to FIG. 1 again, the FETs H1 to H4 used in a current-to-voltage conversion circuit 10 are based on the premise of also operating at room temperature. In general, electronic elements have different operating performance depending on the temperature at which they are used. In the case of a current-to-voltage conversion circuit, all the characteristics and operating requirements such as power supply voltage to be fed to the FETs, conversion efficiency, and noise characteristics vary with temperature. For example, the pseudomorphic FETs of the current-to-voltage converter disclosed in NPL 1 are generally available electronic devices, and operate at both room temperature and low temperatures. This is because the ability to operate at room temperature in a test of electronic elements makes it possible to first perform characterization at room temperature and then selectively and optionally perform costly low-temperature evaluation. In terms of efficiency of testing during mass production of electronic elements and ease of use and evaluation at room temperature, there are significant advantages for both suppliers and users in fabricating electronic elements that operate at room and low temperatures.

However, the current-to-voltage conversion characteristics of FETs operating at both room and low temperatures are inadequate in situations where the FETs are cooled to near absolute zero to measure small currents, such as cosmic rays, quantum device signals, or “quantum fluctuations” of a current. The inventors conceived that if the electronic elements used in the conventional current-to-voltage converter were specialized for operation and performance at low temperatures, more favorable low-noise characteristics could be obtained in low-temperature conditions.

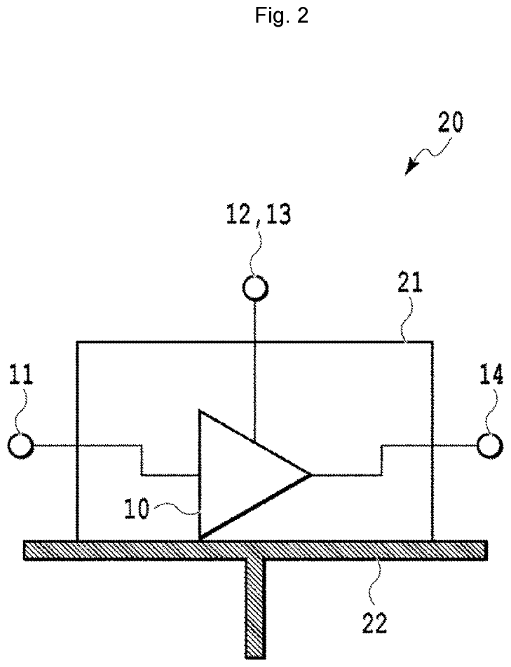

FIG. 2 illustrates a configuration for a low-temperature operation of a current-to-voltage converter. Another problem with the conventional current-to-voltage converter is the limitation imposed by the capability of the cooling device in the case of using the current-to-voltage converter in low-temperature conditions. In a current-to-voltage converter 20 in FIG. 2, the current-to-voltage conversion circuit 10 shown in FIG. 1 is arranged within a cooling device, which has, for example, a cooling stage 22 and a case 21 of the cooling stage 22. Although the current-to-voltage conversion circuit 10 is symbolically shown by a symbol of an amplifier, in practice, the current-to-voltage conversion circuit 10 may be a package of the plurality of elements (FETs) shown in FIG. 1 and other elements on a circuit board. Furthermore, the current-to-voltage conversion circuit 10 may be a circuit in which this package is contained in a case made of oxygen-free copper or the like, and this case is arranged on the stage 22. A current input terminal 11, a voltage output terminal 14, and two power supply terminals 12 and 13 are taken out from inside the case 21.

The cooling device can take various forms, but one example is a dilution refrigerator. The dilution refrigerator is a cylindrical can having a diameter of 0.5 to 1 m×a height of about 2 m that contains the above-described current-to-voltage conversion circuit 10 and has a mechanism for circulating helium inside the can. The dilution refrigerator may also include external mechanisms such as a pump and a compressor for helium circulation, which are not shown in FIG. 2. Examples of other types of available cooling devices and cooling temperatures include, for example: a dilution refrigerator: about 10 mK to 1 K, a 3He refrigerator: about 300 mK, a 4He refrigerator: about 1.5K, liquid helium: 4.2 K, liquid nitrogen: 77 K, and a refrigerant-free pulse tube refrigerator: 1.5 K to 300 K. Note that the form of the case and cooling stage varies depending on the type of cooling device.

In order to sensitively measure small currents using a current-to-voltage converter circuit, it is assumed to be used in combination with a cooling device as shown in FIG. 2. Since the aforementioned cooling device has a finite cooling capacity, it is necessary to keep the power consumption of the current-to-voltage converter 10 arranged inside low. At the same time, it is necessary to minimize the heat flowing into the cooling system from the outside. Even with the most advanced cooling system, it is difficult to maintain cryogenic temperatures if it contains electronic circuits with large power consumption or if there is a large amount of heat flowing into the cooling system from the outside.

“Cooling capacity” is known as an important indicator of a cooling device, and indicates how many watts or less of heat generation in the cooling device is required to maintain a certain temperature. In other words, it means the maximum amount of heat generated that can be tolerated with respect to a cooling target in the cooling device. For example, in the case of a cooling device (dilution refrigerator) for achieving a low temperature of about milli-Kelvin, the typical cooling capacity is about 500 μW at 100 mK in the most advanced device. This means that in order to maintain a low temperature of 100 mK, the power consumption generated in the cooling device needs to be or 500 μW or less. Therefore, the indicator “cooling capacity” may be higher as the temperature set by the cooling device is higher. For example, if the temperature is maintained at 200 mK, the heat generated by a cooling object, i.e., the power consumption in the cooling system may be twice as large as that in the case of 100 mK.

In general, the lower the temperature of an electronic circuit, it is possible to further suppress thermal noise and achieve low noise. It is also advantageous to use a current-to-voltage converter in an environment at as low a temperature as possible for the realization of the ultimate low-noise measurements. Accordingly, it is necessary to suppress the power consumption of the current-to-voltage converter as much as possible to a small level relative to the index “cooling capacity” of the cooling device. The conventional current-to-voltage converter (NPL 1) shown in FIG. 1 has a power consumption of 1.5 mW and can only be used at a temperature of 500 mK or more even with the most advanced dilution refrigerator. In order to reduce the load on the cooling device, it is necessary to reduce the power consumption of the current-to-voltage converter and suppress the heat inflow into the cooling device from outside.

The current-to-voltage converter of the present disclosure simultaneously solves the aforementioned problems of insufficient open-loop gain during low-temperature operation and limited capacity of the cooling device by using electronic elements (FETs) specifically configured for low-temperature operation and by the unique configuration of the current-to-voltage conversion circuit.

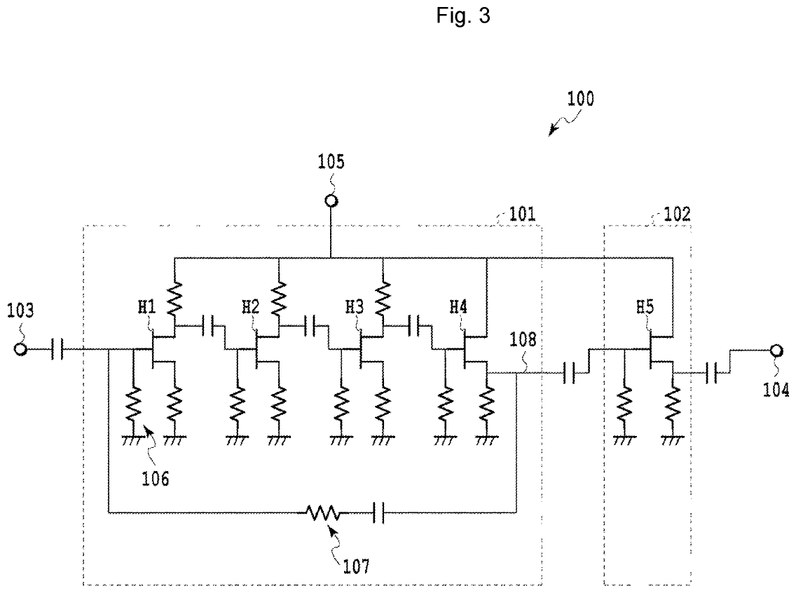

FIG. 3 shows a configuration of a current-to-voltage conversion circuit in a current-to-voltage converter of the present disclosure. The current-to-voltage conversion circuit 100 is roughly divided into a current-to-voltage conversion unit 101 and an output-stage source follower unit 102. The current-to-voltage conversion unit 101 is similar to that in FIG. 1 in its basic amplifier configuration, and includes three FETs (H1 to H3) that constitute common source voltage amplifier stages and a final output stage FET (H4) that is a source follower. An output voltage 108 from the source of H4 is fed back to the gate of H1 via a feedback resistor 107. The gates to the FETs are set to a ground potential by gate resistors 106, and each FET is self-biased by a source resistor using power from a single power supply terminal 105. The abovementioned current-to-voltage conversion unit 101 functions as an amplification unit that converts a target current, which is fed to the first stage, to a voltage while feeding back an output signal of the final stage to the first stage.

The output-stage source follower unit 102 is not included in the conventional current-to-voltage conversion circuit 10 in FIG. 1. That is, in the current-to-voltage conversion circuit 100 of the present disclosure, a FET (H5) of the output-stage source follower unit 102 prevents the frequency characteristics of the current-to-voltage conversion circuit 100 from deteriorating due to stray capacitance of a coaxial cable for extracting the voltage output from the cooling system when the cable is connected to the downstream side of an output voltage terminal 104. In general, a source follower at an output of a circuit is used to reduce output impedance of the circuit and avoid variations in its own operation that it undergoes due to the connection to the next stage circuit. That is, the output-stage source follower unit 102 is connected to the amplification unit, and functions as a buffer unit that outputs the voltage obtained by converting the target current.

When measuring a current at room temperature at which current consumption is not limited, a large current can be applied to the source follower (H4) of the current-to-voltage conversion unit 101. However, it was found that a single-stage source follower was not sufficient when a current-to-voltage converter is used at cryogenic temperatures based on the premise of the use of a cooling device. There is a limit to the power consumption that can be allocated to the source follower FET, and the output impedance of the source follower cannot be reduced sufficiently. Therefore, the output-stage source follower unit 102 is further provided, making it possible to prevent deterioration of the frequency characteristics in the current-to-voltage conversion characteristics due to the cable stray capacitance on the downstream side. By using later-described low-current FETs specialized for low-temperature operation, which will be discussed later, the increase in the number of amplification stages (from 4 to 5) can be compensated for, and smaller current consumption can also be achieved in the entire current-to-voltage conversion circuit. As a result, the load on the cooling device in cryogenic measurement is reduced, while at the same time wide-band small current measurement is realized.

One of the characteristic points of the current-to-voltage converter of the present disclosure is that the power supply voltage is fed to the gates of the FETs at the amplification stages H1 to H5 using the self-bias method. That is, the gate of each FET is connected to ground by a gate ground resistor 106, and the gate is fixed at OV. Since there is also resistance between the source and ground, if a voltage is fed to the drain from the power supply terminal 105, the source potential is positive. Accordingly, when n-type HEMTs are used, it is equivalent to applying a negative voltage between the gate and the source. If appropriate values are selected for the gate and source resistors, an appropriate power supply voltage is fed to each FET in the self-bias method by providing only one power supply terminal 105.

In the conventional current-to-voltage conversion circuit 10 shown in FIG. 1, a power supply terminal 13 for drain and a power supply terminal 12 for gate are independently required for the four FETs (H1 to H4). For this reason, it is necessary to connect the inside and the outside of the cooling device shown in FIG. 2 using at least two electrical wires. The heat inflow from these two electrical wires into the cooling device is the load on the cooling device. If a plurality of small currents are to be measured, a plurality of current-to-voltage conversion circuits need to be housed in the cooling device. However, the need for at least two wires is also a problem in terms of space inside the refrigerator.

The amount of heat inflow per wire can be estimated from the metal material used for the wires and the length of each wire determined by the structure of the refrigerator. Materials commonly used for the wires at low temperatures are copper-nickel alloys, stainless steel, superconducting wires, or the like. A superconducting wire has the lowest thermal conductivity. However, since the wires are only used at cryogenic temperatures of 4 K or less, estimation is made here for the case of using a coaxial cable made of cupronickel (a copper-nickel alloy), which is widely used. In the case of a cable with a thickness (0.86 mmφ) that is easy to use and commonly used, the thermal conductivity is about 0.07 mW·m/K, for example. If it is assumed that the temperature is cooled to 4 K, and a 1-m wire is used while taking an example of a standard cooling device size, the amount of heat inflow per wire is about 0.2 mW. The amount of heat inflow of 0.2 mW is too large to ignore compared to the power consumption of 0.75 mW in the current-to-voltage converter itself.

In contrast, according to the current-to-voltage conversion circuit 100 of the present disclosure shown in FIG. 3, only one power supply wire is needed. This configuration can almost halve the heat flowing into the cooling device from outside via the electrical wire. From the viewpoint of the important indicator “cooling capacity” as well, it is clear that the load on the cooling device can be reduced. Furthermore, even if a plurality of current-to-voltage converters are housed in the cooling device, the effect of reducing wiring space and heat inflow can be obtained.

Another characteristic point of the current-to-voltage converter of this disclosure lie in that FETs with a configuration specialized for low-temperature operation are used as the FETs (H1 to H5) of the current-to-voltage conversion circuit in FIG. 3. Examples of FETs specialized for low-temperature operation include GaAs—based HEMTs, specifically n-AlₓGa₁₋ₓAs/GaAs HEMTs and GaAs quantum well HEMTs. GaAs—based HEMTs exhibit high electron mobility at low temperatures, and therefore operate as broadband and low-noise FETs and facilitate fabrication of elements with large transconductance at low temperatures.

Here, a more specific description will be given to characteristics between the FET that operates at both room and low temperatures used in the conventional current-to-voltage converter and the FET specialized for low-temperature operation used in the current-to-voltage converter of the present disclosure. The HEMTs (FETs) used in the current-to-voltage conversion circuit 100 shown in FIG. 3 have a GaAs—AlGaAs modulation-doped superlattice structure. Pseudomorphic HEMTs and InP-based HEMTs can also be used. These HEMTs can operate at low temperatures and have excellent noise characteristics.

Accordingly, the current-to-voltage converter of the present disclosure can be implemented as a device that includes the amplification unit 101 that has at least three stages each including an electronic element, and converts a target current, which is fed to the first stage, to a voltage while feeding back the output signal of the final stage to the first stage, and the buffer unit 102 that is connected to the amplification unit and outputs the converted voltage. Here, the electronic element is a field-effect transistors (FETs) adapted for operation at a temperature of 150 K or less, the gate of the FET is connected to a ground potential, and a single common power supply 105 is fed to each FET.

In HEMTs, the configuration of the channel portion is related to the detection sensitivity for small currents. Considering the cross-sectional structure of the HEMTs, the channel is formed between the drain and the source. A current at the channel is controlled by an input signal to the gate. In the case of a HEMT that operates at room temperature, the thickness d of the gate insulating layer needs to be sufficiently large in order to reduce leakage current between the channel and the gate. Accordingly, the HEMT capable of operating at both room and low temperatures usually has an insulating layer thickness d of 100 nm or more. Meanwhile, the larger the thickness d, the smaller the response to a change in gate voltage, and the lower the detection sensitivity to an input signal to the gate.

In the GaAs—AlGaAs HEMT with a channel width of 3 mm specialized for low-temperature operation used in the current-to-voltage converter of the present disclosure, the insulating layer thickness d at a temperature 4 K is set to be 100 nm or less; more specifically, 55 nm. When this HEMT is used as an amplifier element, the electrical resistance between the gate and the channel is 200 kQ/mm in actual measurement at room temperature. Thus, this HEMT cannot be used due to its large leakage behavior. In contrast, for example, at liquid helium temperature (4.2K), the electrical resistance between the gate and the channel is 1 GΩ/mm or more, and thus the leakage current can be ignored. By abandoning normal operation at room temperature and using a HEMT specialized for low-temperature operation, the current detection sensitivity of the HEMT serving as the current-to-voltage conversion circuit for cryogenic temperature can be greatly improved.

In HEMTs for room-temperature operation, it is important in general to suppress leakage between the gate and the channel. In GaAs—AlGaAs HEMTs, the gate and the channel are naturally insulated since the Schottky barrier is formed. However, the insulating layer needs to be made thick to some extent. A configuration of a commonly available GaAs—AlGaAs HEMT is disclosed, for example, in NPL 2, where the thickness of the insulating layer is 210 nm, although the amount of doping is not mentioned. Although different materials require different insulating layer thicknesses, a thickness of 100 nm or more is generally considered to be common in the case of GaAs—AlGaAs. The current-to-voltage converter of the present disclosure adopts a configuration specialized for low-temperature operation, with a gate insulating layer having a thickness of 100 nm or less, which cannot be selected for room temperature operation, and simplifies the configuration of power supply to the current-to-voltage conversion circuit to achieve current-to-voltage conversion characteristics that are significantly superior to those of conventional technique.

Here, the configuration of the HEMT specialized for low-temperature operation will be mentioned further. In a current-to-voltage conversion circuit, the shorter the distance between the gate and the channel and the thinner the gate insulating layer, the better in order to increase the current detection sensitivity, as mentioned above. Further, the larger the amount of change in channel current (transconductance) with respect to the gate voltage, the better. Thus, the larger the amount of doping, the higher the current detection sensitivity.

However, the two conditions of the gate insulating layer thickness and the doping amount can only be optimized within the range where no carrier is generated in the gate insulating layer. It is known that beyond this range, a gate leakage current occurs at room temperature, and parallel conduction reduces mobility and degrades HEMT characteristics. If carriers are generated in the gate insulating layer of the HEMT and a gate leakage current flows, the HEMT cannot be used as a current-to-voltage conversion circuit, or even as an electronic element as it does not have the basic operation and performance at room temperature.

In order to ensure the aforementioned basic operation as an electronic element, most of the commercially available HEMTs have a barrier layer, which is a part of the gate insulating layer, with a thickness of 100 nm or more, for example. According to NPL 2, the barrier layer is 180 nm, and the total gate thickness of the three-layer structure is 210 nm. A HEMT with a configuration having such a thick gate insulating layer is a barrier to highly sensitive measurements conducted at low temperatures.

In the current-to-voltage conversion circuit of the present disclosure, a current-to-voltage conversion circuit was prototyped using HEMTs with a gate insulating layer thickness of 55 nm to which delta doping (6×10¹¹ cm⁻²) was performed twice (equivalent to a channel carrier density of 4×10¹¹ cm⁻²), and excellent noise performance was confirmed. These HEMTs have a gate resistor with an electrical resistance of 200 kΩ/mm in actual measurement at room temperature, and cannot be used as HEMTs at room temperature due to leakage current. However, by using the above-described HEMT specialized for low-temperature operation at very low temperatures and simplifying the configuration of power supply to the current-to-voltage conversion circuit as shown in FIG. 3, high sensitivity and low power consumption can be achieved. As a possible guide for a HEMT configuration specialized for low-temperature operation, the gate insulating layer thickness is 100 nm or less, preferably 55 nm or less, and the doping amount is more than equivalent to a channel carrier density of 4×10¹¹ cm⁻².

As described above in detail, small current measurement with excellent sensitive can be realized in extremely low-temperature conditions by the current-to-voltage converter of the present disclosure. Industrial Applicability

### INDUSTRIAL APPLICABILITY

The present invention can be used in highly sensitive measurement of small currents.

### REFERENCE SIGNS LIST

10, 100 Current-to-voltage conversion circuit

11, 103 Current input terminal

12, 13, 105 Power supply terminal

14, 104 Voltage output terminal

15, 107 Feedback resistor

20 Current-to-voltage converter

21 Case

22 Cooling stage

108 Drain output voltage

1. A current-to-voltage converter comprising:
an amplification unit having at least three stages each including an electronic element and configured to convert a target current, which is fed to a first stage, to a voltage while feeding back an output signal of a final stage to the first stage; and
a buffer unit connected to the amplification unit and configured to output the converted voltage,
wherein the electronic element is a field-effect transistor (FET) adapted to operation at a temperature of 150 K or less, a gate of the FET is connected to a ground potential, and a single common power supply is fed to each FET

2. The current-to-voltage converter according to claim 1, wherein
the amplification unit has four common source voltage amplifier stages, and the final stage constitutes a source follower, and
the buffer unit is a source follower that includes the electronic element.

3. The current-to-voltage converter according to claim 1, wherein
the FET is a high electron mobility transistor (HEMT), and has a gate insulating layer is 100 nm or less.

4. The current-to-voltage converter according to claim 3, wherein
the HEMT is a HEMT with a GaAs—AlGaAs modulation-doped superlattice structure, a pseudomorphic HEMT, or an InP-based HEMT.

5. A small current measurement device comprising the current-to-voltage converter according to claim 1, the current-to-voltage converter being provided within a cooling device.

6. The current-to-voltage converter according to claim 2, wherein
the FET is a high electron mobility transistor (HEMT), and has a gate insulating layer is 100 nm or less.

7. A small current measurement device comprising the current-to-voltage converter according to claim 2, the current-to-voltage converter being provided within a cooling device.

8. A small current measurement device comprising the current-to-voltage converter according to claim 3, the current-to-voltage converter being provided within a cooling device.

9. A small current measurement device comprising the current-to-voltage converter according to claim 4, the current-to-voltage converter being provided within a cooling device.
